(19) United States
(12) Patent Application Publication
(10) Pub. No.: US 2023/0275617 A1
(43) Pub. Date: Aug. 31, 2023

(54) AUDIO DEVICE WITH HALL EFFECT SENSOR PROXIMITY DETECTION AND INDEPENDENT COUPLING

(71) Applicant: Bose Corporation, Framingham, MA (US)

(72) Inventors: John Leslie Benton, Northbridge, MA (US); Caitlin Mary Hanson, Westborough, MA (US); Thomas David Chambers, Bellingham, MA (US); Fardad Faridi, Marlborough, MA (US); Josue Abraham Malaver Gomez, Millbury, MA (US)

(21) Appl. No.: 17/588,626

(22) Filed: Jan. 31, 2022

(51) Int. Cl. H04B 5/00; G01R 33/07; G01D 5/14; H02J 7/00

(52) U.S. Cl. CPC H04B 5/00; G01D 5/145; G01R 33/07; H02J 7/0044

(57) ABSTRACT

Various implementations include audio devices such as earbuds or earpieces. In certain cases, an audio devices includes a set of earbuds configured to generate a magnetic field. The audio device also includes a case for docking the set of earbuds. The case includes: a Hall effect sensor for detecting proximity to at least one of the earbuds based on the magnetic field; and a power source for charging the set of earbuds while docked in the case. Additional implementations include independent couplings for earbuds or earpieces.

### TECHNICAL FIELD

This disclosure generally relates to audio devices. More particularly, the disclosure relates to detecting audio device proximity in a storage and/or charging case, and mechanisms for coupling untethered audio devices (e.g., earbuds) to mitigate loss and/or damage.

### BACKGROUND

Detecting presence of audio devices in casings can be beneficial, e.g., for controlling device functions and limiting battery usage. Additionally, preventing the loss or damage of untethered audio devices (e.g., earbuds) is desirable.

### SUMMARY

All examples and features mentioned below can be combined in any technically possible way.

Various aspects include an audio device including: a set of earbuds each configured to generate a magnetic field; and a case for docking the set of earbuds, the case including: a Hall effect sensor for detecting proximity to at least one of the earbuds based on the magnetic field; and a power source for charging the set of earbuds while docked in the case.

In certain additional aspects, an audio device includes: a case having at least one magnet; and a set of earbuds for docking in the case, wherein each earbud comprises a Hall effect sensor for indicating proximity to the at least one magnet to indicate that a corresponding earbud is docked in the case.

In further aspects, an open-ear audio device includes: a first open-ear earpiece housing an electro-acoustic transducer and including a first coupler; a second open-ear earpiece housing an electro-acoustic transducer and including a second coupler, where the first coupler and the second coupler are configured to couple the first open-ear earpiece and the second open-ear earpiece while not in use on a user’s ears.

In additional aspects, an open-ear audio device includes: a first open-ear earpiece housing an electro-acoustic transducer and including a first coupler; a second open-ear earpiece housing an electro-acoustic transducer and including a second coupler; and a common connector for coupling with the first coupler and the second coupler while the first open-ear earpiece and the second open-ear earpiece are not in use on a user’s ears, wherein the first coupler is integral with the first open-ear earpiece and the second coupler is integral with the second open-ear earpiece.

In additional particular aspects, a method includes detecting docking in and/or removal from an earbud case of a set of earbuds based on a signal received from a Hall effect sensor in the earbud case or a Hall effect sensor in the set of earbuds.

Implementations may include one of the following features, or any combination thereof.

In some cases, each earbud includes an electro-acoustic transducer configured to generate the magnetic field, and the Hall effect sensor is sensitive to the magnetic field generated by the electro-acoustic transducer to detect the proximity to one of the earbuds.

In particular aspects, each earbud includes at least one magnet that generates the magnetic field. In some implementations, the magnet(s) are located in the battery barrel of the earbud.

In certain cases, the set of earbuds include a pair of in-ear audio devices or open-ear audio devices that are untethered relative to one another.

In some implementations, the earbuds include the open-ear audio devices.

In particular cases, the open-ear audio devices include ear cuffs.

In certain aspects, the audio device further includes at least one additional Hall effect sensor for detecting proximity to an additional one of the set of earbuds or detecting an orientation of at least one of the set of earbuds. In some examples, the Hall effect sensor(s) are oriented to detect an earbud once seated in a slot in the case. In particular examples, the Hall effect sensor(s) are positioned to be sensitive to one or both earbuds being present in the case.

In particular implementations, the Hall effect sensor is configured to detect the magnetic field from each earbud regardless of a power state of the earbud. In some examples, the Hall effect sensor is configured to detect the magnetic field from each earbud even when the earbud battery is depleted beyond a threshold to provide a voltage-based measurement, such as when the battery is at or below several percent charge.

In some cases, each earbud further includes an additional Hall effect sensor and the case further includes at least one magnet, where the additional Hall effect sensor in each earbud is configured to perform at least one of: indicate proximity to the case based on a detected magnetic field from the at least one magnet, or indicate proximity to the other one of the earbuds based on detecting the magnetic field generated by the corresponding earbud. In some examples, indicating proximity to the case can be used to verify proximity and/or docking of an earbud, or can be used independently. In additional examples, indicating proximity to another earbud can trigger a change in operating mode, for example, switching to a sleep mode, shutdown, and/or pausing or stopping audio playback in response to detecting close proximity between earbuds that is indicative of the earbuds being off-head.

In certain aspects, the case is configured to initiate a charging protocol for charging the earbuds in response to the Hall effect sensor detecting proximity to at least one of the earbuds. In particular examples, the case includes a set of slots for docking the earbuds, and a controller coupled with the Hall effect sensor and the power source. In additional examples, docking can be orientation-specific, e.g., left orientation as compared with right orientation.

In particular implementations, the case further includes: an additional Hall effect sensor for detecting a magnetic field generated by each of the set of earbuds; and a power source for charging the set of earbuds while docked in the case.

In some cases, each earbud includes an electro-acoustic transducer configured to generate a magnetic field, and the additional Hall effect sensor is sensitive to the magnetic field generated by the electro-acoustic transducer to detect the proximity to one of the earbuds.

In certain aspects, the set of earbuds includes open ear audio devices. In some examples, the open ear audio devices include ear cuffs.

In particular cases, the first coupler and the second coupler each include a magnet for coupling the first open-ear earpiece and the second open-ear earpiece. In certain examples, the magnets can be located in the battery barrel of the earpiece to orient the ear cuffs in a same direction, e.g., side-by-side.

In some implementations, the magnets are detectable by a Hall effect sensor in a charging case for the first open-ear earpiece and the second open-ear earpiece.

In certain aspects, the first coupler and the second coupler include complementary connectors for coupling the first open-ear earpiece and the second open-ear earpiece.

In particular implementations, the complementary connectors include at least one of: a snap-fit connector, an interlocking connector, a force-fit connector, or a magnet.

In some cases, the first open-ear earpiece and the second open-ear earpiece are untethered such that first coupler and the second coupler provide approximately all of a retaining force in coupling the first and second earpieces.

In certain aspects, the first coupler and the second coupler retain the first and second earpieces together independently of a charging case or a storage case.

In some implementations, the audio device further includes a removable tether configured to connect to at least one of the first open-ear earpiece or the second open-ear earpiece.

In particular cases, the removable tether includes a connector for connecting to an external power source or an external data source. In some examples, one end of the tether connects to a power and/or data input, and another end of the connector is coupled to the ear cuffs. In certain examples, the connector includes a USB connector.

In certain implementations, when the removable tether is connected to the first open-ear earpiece and the second open-ear earpiece and the first coupler and second coupler are connected, the open-ear audio device forms an annular piece of jewelry or a keychain.

In particular cases, the removable tether includes a backup battery and a connector for at least one of charging an onboard battery at the open-ear earpieces or directly powering the open-ear earpieces.

In some aspects, the audio device further includes a charging dish for charging an onboard battery in each of the open-ear earpieces when connected.

In particular cases, the common connector includes a tether.

In certain aspects, the common connector includes a power connector for charging the first open-ear earpiece and the second open-ear earpiece independently of a charging case.

In some implementations, the first coupler and the second coupler are complementary to permit direct coupling of the first open-ear earpiece to the second open-ear earpiece.

In particular aspects, the first coupler and the second coupler include magnets.

In certain cases, a Hall effect sensor is located in the earbud case and/or in the set of earbuds.

In some examples, a method further includes initiating charging of the set of earbuds in response to detecting docking of the set of earbuds in the earbud case.

Two or more features described in this disclosure, including those described in this summary section, may be combined to form implementations not specifically described herein.

The details of one or more implementations are set forth in the accompanying drawings and the description below. Other features, objects and advantages will be apparent from the description and drawings, and from the claims.

### BRIEF DESCRIPTION OF THE DRAWINGS

FIG. 1 is a schematic depiction of an audio device according to various implementations.

FIG. 2 is a perspective view of an earbud according to various implementations.

FIG. 3 is a schematic depiction of electronics in an audio device according to various implementations.

FIG. 4 is a schematic depiction of electronics in an audio device case according to various implementations.

FIG. 5 is a perspective view of an audio device case according to various implementations.

FIG. 6 shows a partial cut-away view of a portion of the case in FIG. 5.

FIG. 7 is a perspective view of an audio device case according to various implementations.

FIG. 8 is a perspective view of a set of audio devices according to various implementations.

FIG. 9 is a perspective view of a set of audio devices according to various implementations.

FIG. 10 is a perspective view of a set of audio devices and a tether according to various implementations.

FIG. 11 is a perspective view of a tether according to various implementations.

FIG. 12 illustrates an audio device and tether according to various implementations.

FIG. 13 illustrates an audio device in a case according to various implementations.

It is noted that the drawings of the various implementations are not necessarily to scale. The drawings are intended to depict only typical aspects of the disclosure, and therefore should not be considered as limiting the scope of the implementations. In the drawings, like numbering represents like elements between the drawings.

### DETAILED DESCRIPTION

This disclosure is based, at least in part, on the realization that a Hall effect sensor can be used in an audio device (e.g., earbud) case to aid in detecting proximity of the device (e.g., one or more earbuds). This disclosure is further based, at least in part, on the realization that a Hall effect sensor can be used in one or more earbuds in a set to indicate docking of the earbud(s) in a case, and/or to indicate proximity between the earbuds. This disclosure is further based, at least in part, on the realization that an open-ear audio device with separate earpieces (e.g., ear cuffs) can include an integrated coupler for coupling the earpieces together, or to a common connector such as a tether or a piece of jewelry.

Commonly labeled components in the FIGURES are considered to be substantially equivalent components for the purposes of illustration, and redundant discussion of those components is omitted for clarity. Numerical ranges and values described according to various implementations are merely examples of such ranges and values, and are not intended to be limiting of those implementations. In some cases, the term “approximately” is used to modify values, and in these cases, can refer to that value +/- a margin of error, such as a measurement error, which may range from up to 1-5 percent.

Aspects and implementations disclosed herein may be applicable to a wide variety of wearable audio devices in various form factors, such as head-worn devices (e.g., headsets, headphones, earphones, eyeglasses, helmets, hats, visors,), neck-worn speakers, shoulder-worn speakers, body-worn speakers (e.g., watches), etc. Some particular aspects disclosed may be applicable to personal (wearable) audio devices such as in-ear audio devices or on-ear audio devices, referred to collectively herein as earbuds. Additional particular aspects disclosed may be applicable to wearable audio devices such as tethered or untethered open-ear headphones, referred to as ear cuffs. It should be noted that although specific implementations of audio devices primarily serving the purpose of acoustically outputting audio are presented with some degree of detail, such presentations of specific implementations are intended to facilitate understanding through provision of examples and should not be taken as limiting either the scope of disclosure or the scope of claim coverage.

The wearable audio devices disclosed herein can include additional features and capabilities not explicitly described. These wearable audio devices can include additional hardware components, such as one or more cameras, location tracking devices, microphones, etc., and may be capable of voice recognition, visual recognition, and other smart device functions. The description of wearable audio devices included herein is not intended to exclude these additional capabilities in such a device.

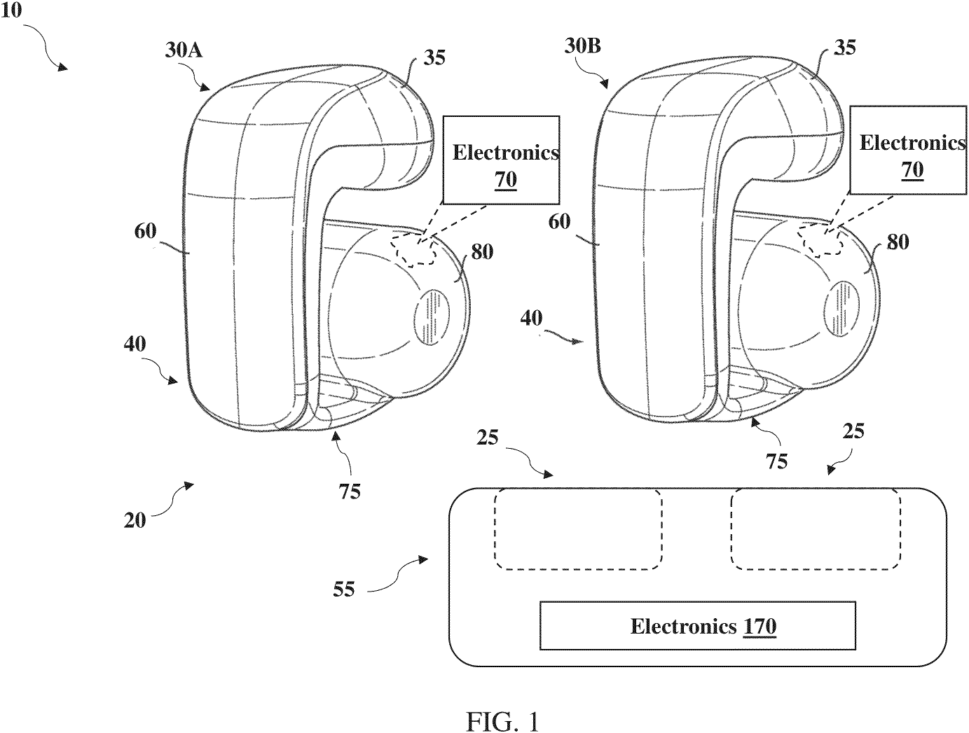

In particular implementations, FIG. 1 illustrates an example of systems and devices that may incorporate the teachings of the various implementations. This example is not intended to be limiting.

FIG. 1 is a schematic depiction of an example audio system 10. In this example, the audio system 10 includes an audio headset 20 having a pair of audio devices 30, which in this particular implementation, are two distinct earbuds such as open-ear headphones 30A, 30B as described in U.S. Pat. No. 11,140,469 (“Open-Ear Headphone”), the entirety of which is incorporated by reference. While the audio devices (also called ear cuffs, or headphones herein) 30 are shown in a “true” wireless configuration (i.e., without tethering between earbuds), the audio headset 20 could also include a tethered wireless configuration (whereby the earbuds are connected via wire with a wireless connection to a playback device) or a wired configuration (whereby at least one of the earbuds has a wired connection to a playback device).

Devices 30A, 30B (e.g., open-ear headphones, or ear cuffs), include an acoustic module configured to be located at least in part in a concha of an outer ear of a user. The device 30A, 30B is configured such that when the acoustic module is placed into the cavum conchae of the ear the body passes over at least one of the antihelix, the helix, and the lobule of the ear. In an example, the body is generally “L”-shaped and the acoustic module and body together (i.e., the entire open-ear headphone) is generally “C”-shaped. In an example, the center of gravity of the open-ear headphone is between the acoustic module and the second portion of the body. The center of gravity can be located in or near the part of the outer ear that is between the acoustic module and the second portion of the body (e.g., the helix or lobule). As shown in FIG. 1, device 30A, 30B includes an acoustic module 35 that is sized, shaped, and located relative to the open-ear headphone body 40 such that the acoustic module 35 is configured to be located in the concha of the outer ear of the user. Generally, the outer ear (also known as the auricle or pinna) of a human includes a concha that is immediately adjacent to the entrance to the ear canal, which is underneath (or, behind) the tragus. The concha is divided by the helix crus into a lower portion termed the cavum conchae and an upper portion termed the cymba conchae. The cavum conchae is a generally bowl-shaped feature that is directly adjacent to the ear canal. The cavum conchae typically includes a depression bordered by the antitragus, which is the lower part of the anti-helix and/or bordered by the lobule. The lobule (i.e., the earlobe), which is at the lower end of the helix, is typically just below the antitragus. The body 40 is coupled to acoustic module 35 and includes a first portion 60 that is configured to pass over the outer side of the ear (e.g., at least one of the anti-helix and helix and lobule of the outer ear), and a second portion 80 that is configured to be located behind the outer ear. Body 40 is generally “L”-shaped from the side (as shown in FIG. 1) with portion 60 running at about a right angle to acoustic module 35, connecting portion 75 running at about a right angle to portion 60 and leading to distal portion 80. In an example, portion 80 can be generally cylindrical such that it is configured to hold a generally cylindrical battery power source (e.g., a rechargeable battery). Overall, device 30 (e.g., open-ear headphone) is generally “C”-shaped, as shown in FIG. 1. In an example, acoustic module 35 and body 40 are parts of a unitary molded plastic housing that is constructed and arranged to contain the transducer, the battery, and any necessary electronics for operation of the headphone.

The body 40 can include a casing formed of one or more plastics or composite materials. In this example configuration, the body 40 can include a an outer casing for housing electronics 70, which can include components of an interface. As described herein according to various implementations, the body 40 (including, e.g., outer casing) can include at least one magnet (e.g., internal to the casing). In certain implementations, as described herein, the magnet(s) can be positioned to enable magnetic coupling of audio devices 30A, 30B, and/or proximity-based detection by another device (e.g., a storage and/or charging case, or another audio device). As also described herein according to various implementations, the body 40 can include at least one Hall effect sensor that can, for example, aid in proximity detection and related functions.

In some cases, separate, or duplicate sets of electronics 70 are contained in portions of the audio device 30, e.g., each of the respective audio devices 30. However, certain components described herein can also be present in singular form. In some examples, the system 10 includes an additional device 55, which in this example is a docking station or case (e.g., charging case) for the audio devices (open-ear headphones 30). In various implementations, the case 55 is configured to house the devices 30A, 30B (e.g., for storage) and in some cases can include a power source or connection to a power source for charging the headphones 30A, 30B. The case 55 can include electronics 170, some of which may be similar to electronics 70 in the open-ear headphones 30A, 30B. Receptacles (e.g., slots, seats, or other openings) 25 are shown in phantom within the case 55 for holding the headphones 30A, 30B. The receptacles 25 can each be sized to receive a headphone 30A, 30B. As described herein, receptacles 25 can be sized to receive the headphones 30A, 30B in a particular (e.g., only one) orientation.

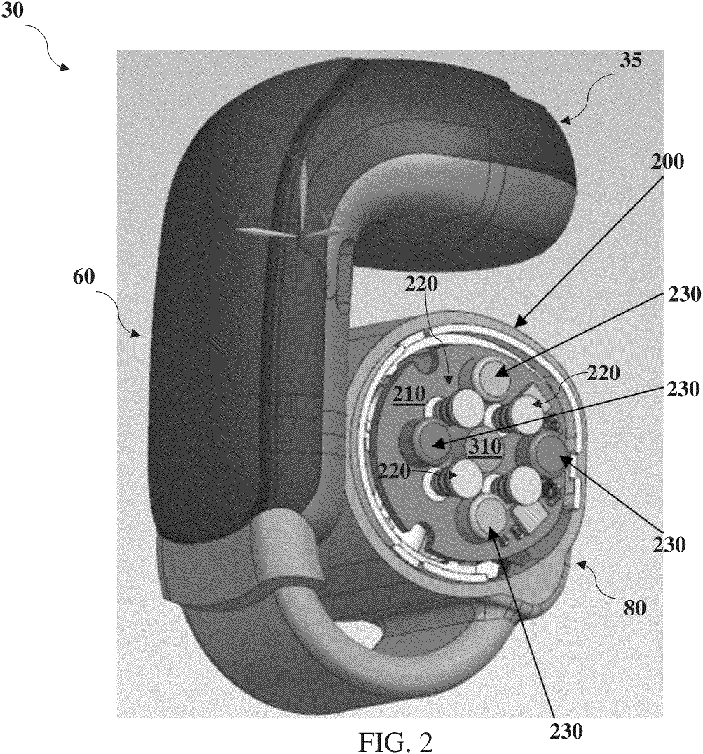

FIG. 2 shows a cut-away view of the portion 80 of device 30, e.g., illustrating the battery barrel 200, including a printed circuit board (PCB) 210 coupled with a set of battery cells 220, and one or more magnets 230. In this example, a plurality of magnets 230 are arranged on an outer surface of the PCB 210. In certain implementations, magnets 230 are located in a distinct portion of the device 30, e.g., in the body 40 or proximate the acoustic module 35. As described herein, in optional implementations, the device 30 can include a Hall effect sensor 310 for example, to aid in proximity detection functions.

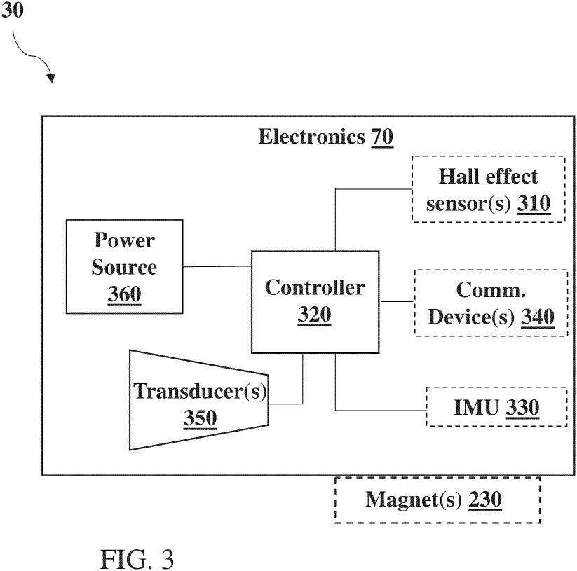

Example electronics 70 in audio devices 30 are depicted in schematic form in FIG. 3. Additionally, magnets 230, which can be located adjacent to an electronics compartment or contained with one or more portions of the electronics 70 in audio devices 30 are illustrated in FIG. 3.

It is understood that one or more of the components in electronics 70 may be implemented as hardware and/or software, and that such components may be connected by any conventional means (e.g., hard-wired and/or wireless connection). It is further understood that any component described as connected or coupled to another component in the devices or other systems disclosed according to implementations may communicate using any conventional hard-wired connection and/or additional communications protocols. In some cases, communications protocol(s) can include a Wi-Fi protocol using a wireless local area network (LAN), a communication protocol such as IEEE 802.11 b/g a cellular network-based protocol (e.g., third, fourth or fifth generation (3G, 4G, 5G cellular networks) or one of a plurality of internet-of-things (IoT) protocols, such as: Bluetooth, BLE Bluetooth, ZigBee (mesh LAN), Z-wave (sub-GHz mesh network), 6LoWPAN (a lightweight IP protocol), LTE protocols, RFID, ultrasonic audio protocols, etc. In various particular implementations, separately housed components in the systems 10 disclosed herein are configured to communicate using one or more conventional wireless transceivers.

As shown in FIG. 3, electronics 70 contained within each device 30 can include at least one Hall effect sensor 310 and a controller 320 coupled to the Hall effect sensor(s) 310. In certain optional implementations (depicted in phantom), the electronics 70 can further include an inertial measurement unit (IMU) 330 for detecting movement of the device 30 (e.g., through one or more accelerometers, gyroscopes, and/or magnetometers) and enabling particular control functions. In certain optional cases, electronics 70 can also include one or more communications (comm.) devices 340 for sending communications signals to other device(s) 30, pairing devices 30, connecting with audio gateways, etc. In some optional examples, the electronics 70 can also include at least one transducer 350 for providing an audio output, e.g., in a wearable audio device. For example, headphones 30 can include a transducer 350 for providing an audio output. One or more components in the electronics 70 can be connected with the controller 320, which is configured to perform control functions according to various implementations described herein.

In certain cases, the Hall effect sensor 310 is configured to detect proximity to at least one of a set of magnets 230 in a distinct device, e.g., headphones 30 and/or a case 55. Additionally, as described herein according to various implementations, the Hall effect sensor 310 can be configured to detect proximity to any device generating a magnetic field in the headphone(s) 30 and/or case(s) 55. For example, the Hall effect sensor 310 can be used to detect proximity to a device based on a magnetic field generated by one of the electro-acoustic transducers 350. In particular, a Hall effect sensor 310 is configured to sense magnetic flux from nearby magnets such as the magnets 230 in headphone(s) 30 and/or case(s) 55. In additional cases, a Hall effect sensor 310 is configured to sense magnetic flux from nearby transducer(s) 350 in headphone(s) 30.

In additional optional implementations, proximity detection can be aided with an additional short-range wireless transmission system, e.g., in communication devices 340. In these cases, the short-range wireless transmission system can include a near-field communication (NFC) system and/or Bluetooth communication system. These wireless transmission systems can be used to detect, or confirm device proximity, e.g., using signal strength as a measure of physical proximity.

Returning to FIG. 3, in various implementations, the controller 320 in audio device 30 can include a processor (e.g., including a logic engine) to execute instructions for detecting proximity between the audio devices 30 and/or between the audio devices 30 and the corresponding case 55, and controlling device functions. In some cases, a memory is coupled with the processor to store the instructions. In other implementations, the processor can otherwise access the instructions, e.g., from a remote storage system such as a server connected with one or more devices 30 and/or case 55. When executed by the processor in the controller 320, the instructions cause the processor to detect proximity between devices 30 and/or case 55 and take a prescribed action according to that detection. In some cases, the instructions are part of an application, such as a device detection application, which can be accessed via the server or locally stored in memory, e.g., at the controller 320 or in another storage system in the device(s). The memory at the device(s) can include, for example, flash memory and/or non-volatile random access memory (NVRAM). In some implementations, instructions (e.g., software such as a device detection application) are stored in an information carrier. The instructions, when executed by one or more processing devices, perform one or more processes, such as those described elsewhere herein. The instructions can also be stored by one or more storage devices, such as one or more (e.g. non-transitory) computer- or machine-readable mediums (for example, the memory, or memory on the processor). As described herein, the memory can include instructions, or the processor can otherwise access instructions for detecting device proximity and taking a prescribed action according to various particular implementations. It is understood that portions of the memory (e.g., instructions) can also be stored in a remote location or in a distributed location, and can be fetched or otherwise obtained by the processor (e.g., via any communications protocol described herein) for execution.

The IMU 330 can include a microelectromechanical system (MEMS) device that combines a multi-axis accelerometer, gyroscope, and/or magnetometer. It is understood that additional or alternative sensors may perform functions of the IMU 330, e.g., an optical-based tracking system, accelerometer, magnetometer, gyroscope or radar for detecting movement as described herein. The IMU 330 can be configured to detect changes in the physical location/orientation of devices, and provide updated sensor data to the controller 320 in order to indicate a change in the location/orientation of the device (e.g., audio device 30). However, it is understood that the electronics 70 can also include one or more optical or visual detection systems located at the audio device(s) 30 and/or case 55 or another connected device configured to detect the orientation of the audio device(s) and or case. The communication device(s) 340 can include one or more wireless transceivers configured to communicate over any communications protocol described herein. As noted herein, in the audio devices 30, the transducer 350 can include at least one electroacoustic transducer for producing an acoustic output, for example into, or proximate, the ears of a user in the case of a wearable audio device, or into an environment at one or more firing directions in the case of a speaker system.

The electronics 70 can also include a power source 360, which in some instances includes an onboard battery. For example, the power source 360 in the audio devices 30 can include a battery, such as a rechargeable battery.

Additional components included in electronics 70 and not necessarily depicted can include signal amplification and other digital signal processing (DSP) hardware and/or software, active noise reduction (ANR) and/or controllable noise cancelling (CNC) systems, input/output (I/O) devices, displays and/or user interfaces (UIs), etc. It is understood that these components or functional equivalents of these components can be connected with, or form part of, the controller 320.

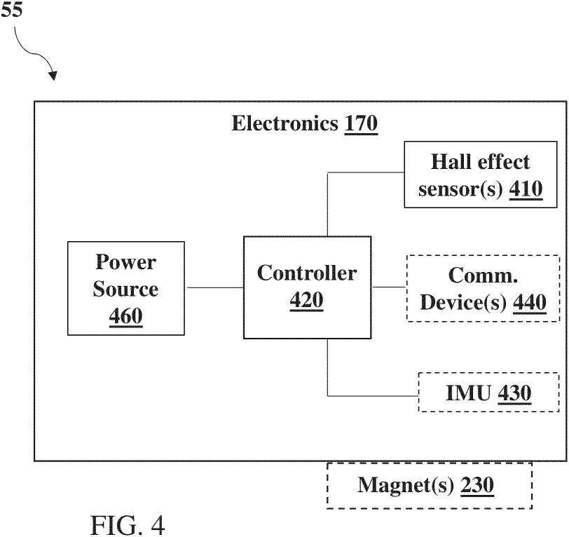

FIG. 4 illustrates electronics 170 in the case 55 according to various implementations. In certain cases, the case 55 can include electronics 170 and additional components (e.g., magnets 230) similar to those described with respect to the electronics 70 in headphones 30. For example, electronics 170 in the case 55 can include Hall effect sensor(s) 410, a controller 420, an IMU 430, communication device(s) 440, and a power source 460. In certain cases, the case 55 includes one or more magnets 230. As noted herein, the Hall effect sensor(s) 410 and/or magnets 230 at the case 55, when coupled with the controller 420, can aid in proximity detection functions described herein.

In certain implementations, the power source 460 in the case 55 includes a rechargeable battery and/or a power connector for coupling with an external power source, e.g., to charge an onboard battery and/or to charge audio devices 30 docked in the case 55. The power source 460 can be coupled with the controller 320 in some cases, however, in other cases, the power source 460 can be directly coupled with one or more of the connectors for charging one of the audio devices 30.

In various implementations, the controller 320 in one or more audio devices (e.g., audio device 30) and/or the controller 420 in the case 55 is configured to perform functions in device detection and control. Distinct functions are illustrated in the following sections.

### Hall Effect Sensor in Case

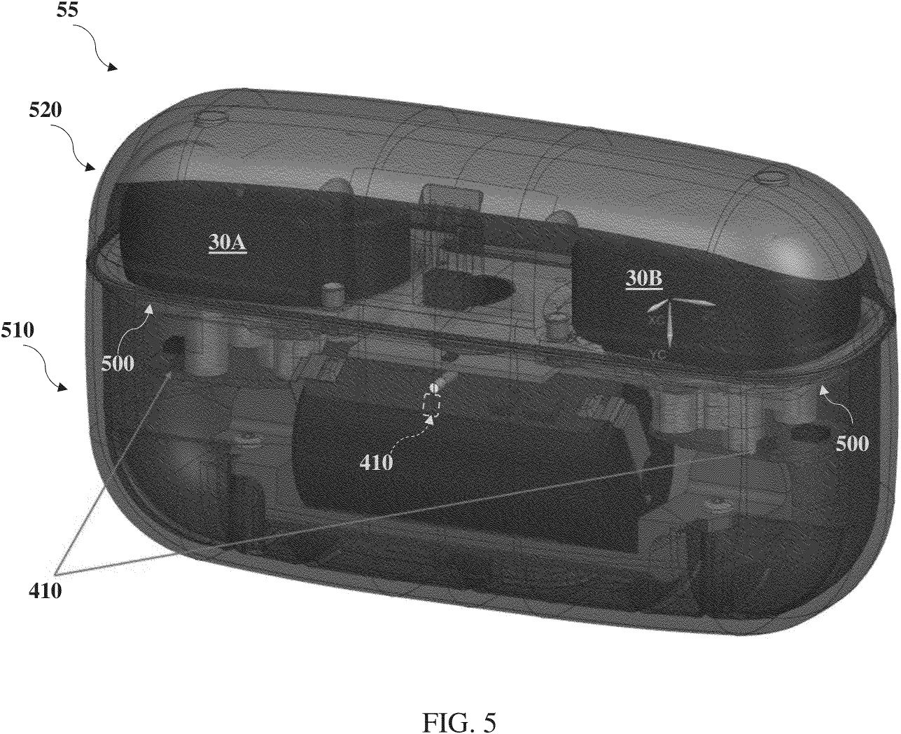

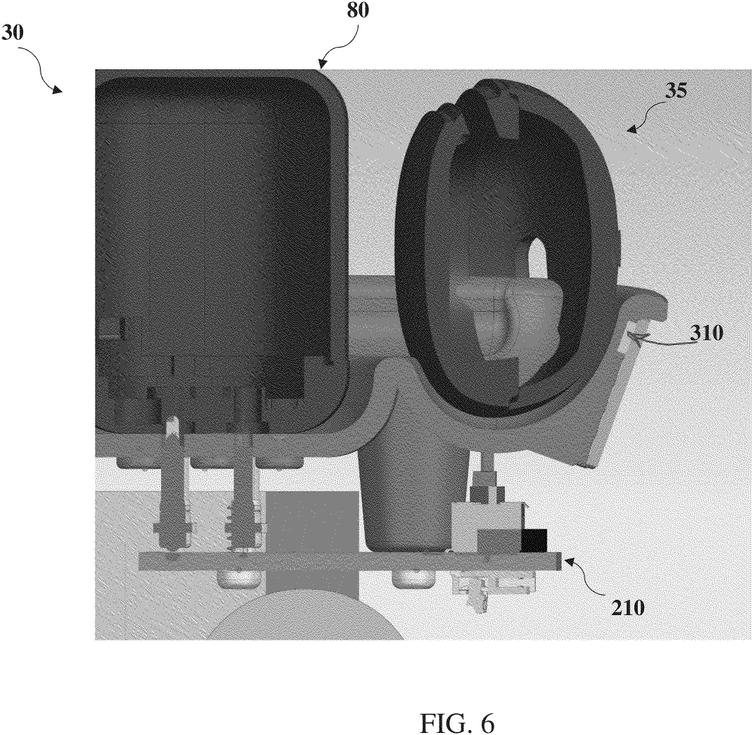

As noted herein, various implementations of a case 55 can include a Hall effect sensor (e.g., Hall effect sensor 410). In a particular example, a partially transparent perspective of a case 55 housing left and right headphones 30A, 30B is shown in FIG. 5. As illustrated, a pair of Hall effect sensors 410 are located in the case 55 proximate to receptacles (e.g., slots 500) for detecting proximity to at least one of the headphones, e.g., ear cuff-type earbuds 30. In this particular example, headphones 30A, 30B are configured to sit within slots 500, and are detectable by the Hall effect sensors 310 while in slots 500. In this example, the case 55 includes a base 510 and a top 520, which are illustrated in a closed position. It is understood that the top 520 can pivot, rotate, slide, etc., relative to the base 510. In certain cases, while seated in the slots 500, a portion of the ear cuff 30 extends between the base 510 and the top 520, such that the base 510 and top 520 collectively define the slots 500 that house the ear cuffs 30. FIG. 6 illustrates a close-up cutaway perspective view of a Hall effect sensor 310 in a headphone 30 (e.g., ear cuff), proximate to circuit board 210 (e.g., printed circuit board). In this view, the acoustic module 35 is illustrated without the transducer, and the battery barrel 80 is shown without internal electronics. In various implementations, the Hall effect sensor 310 is positioned to detect the presence (i.e., proximity) of one or more magnets in another headphone 30, and/or magnets in a case 55. Additionally, the Hall effect sensor 310 can be positioned to detect the proximity to a transducer in another headphone 30.

In certain additional implementations (depicted in phantom as optional), a Hall effect sensor 410 can be positioned between the slots 500 and may be configured to detect the presence of both headphones 30 in slots 500. For example, a Hall effect sensor 410 can be positioned between the headphones 30 to be sensitive to one or both headphones 30 being present in the slots 500 in the case 55. In particular examples, the Hall effect sensor 410 positioned between the slots 500 (illustrated in phantom) can be the sole Hall effect sensor for detecting the presence of both headphones 30 in slots 500.

In some cases, a given Hall effect sensor 410 is positioned to be sensitive to the presence and orientation of a headphone 30, for example, such that the Hall effect sensor 410 will not indicate the headphone 30 is docked in the slot 500 unless its orientation aligns with the slot 500. For example, the slot(s) 500 can be shaped to complement the shape of the headphone 30, such that the headphone 30 can have only one desired orientation in the slot 500. In certain cases, where headphones 30 are left-specific and right-specific earbuds, a given slot 500 will only accommodate one type of the earbuds (e.g., left or right). In such cases, the Hall effect sensor 410 is positioned in the case 55 to only detect the presence of a given headphone 30 when that headphone 30 is docked in the corresponding slot 500 in the desired orientation. The desired orientation can be based on a physical contact location for charging the headphone 30, proximity to an inductive or capacitive charging mechanism, and/or a design feature to minimize the space required to store the headphone(s) 30 in the case 55. In particular implementations, the Hall effect sensors 410 is located adjacent to a portion of the slot 500 that is sized to house a portion of the headphone 30 from which the magnetic flux will be strongest, e.g., proximate the battery barrel 200 and/or proximate the acoustic module 35 housing the transducer(s) 350.

Returning to FIG. 5, in this example, a pair of Hall effect sensors 410 are located adjacent to the headphones 30, such that when seated in slots 500, the headphones 30 are interposed between the two Hall effect sensors 410. As described according to various implementations, the Hall effect sensors 410 can be sensitive to a magnetic field generated by the headphones 30, e.g., to determine that the headphones 30 are docked in the slots 500, and in some cases, oriented as desired in the slots 500. In other terms, the Hall effect sensor 410 determines that the headphone 30 is fully seated in a slot 500. In certain cases, the Hall effect sensor 410 is sensitive to the magnetic flux generated by the transducer(s) 350 in the headphone 30 to detect proximity to the headphone 30. For example, the Hall effect sensor 410 can be positioned in the case 55 such that when fully seated, the acoustic module housing the transducer 350 is adjacent to the Hall effect sensor 410. In this case, the Hall effect sensor 410 is sized and positioned to detect the magnetic flux from the transducer 350 when the headphone 30 is fully seated in the slot 500. It is understood that in certain cases, the Hall effect sensor 410 can be configured to detect the magnetic flux from one or more components in the headphone 30, e.g., the transducer 350, the power source 360 (e.g., battery) and/or an onboard magnet 230.

In certain cases, the Hall effect sensor(s) 410 are configured to detect the magnetic field from each headphone 30 regardless of a power state of the headphone 30. That is, the Hall effect sensor 410 for each slot 500 is positioned to detect the presence of the headphone 30 via its magnetic flux even if the power source 360 (e.g., battery) at the headphone 30 is depleted beyond a threshold sufficient to provide a voltage-based measurement. In other terms, the Hall effect sensor 410 for each slot is positioned to detect a magnetic flux from the headphone 30 in cases where the battery is at or below several percent charged. In some such cases, the Hall effect sensor 410 can detect the presence of the headphone 30 via the magnetic flux of the transducer 350.

In some implementations, the case 55 is configured to initiate a charging protocol for charging headphone(s) 30 in response to the Hall effect sensor 410 detecting proximity to the headphones(s) 30, e.g., indicating that the headphone 30 is fully seated in the slot 500 in case 55. In particular cases, the controller 420 at case 55 (FIG. 4) is configured to initiate the charging protocol in response to receiving a signal from one, or both Hall effect sensor(s) 410 indicating the presence of the headphones 30 in the slots 500 in case 55. In some cases, as noted herein, the Hall effect sensor(s) 410 are positioned to be sensitive to the headphones 30 being fully seated in slots 500. For example, the Hall effect sensor 410 for a given headphone 30 will not detect the presence of the headphone 30 unless it is fully seated in the corresponding slot 500. In such a case, the controller 420 will only take the prescribed action in response to receiving an indicator from the Hall effect sensor 410 that both headphones 30 are docked in the slots 500.

In particular implementations, as depicted in phantom as optional implementations in FIGS. 3 and 4, one or more headphones 30 can include a Hall effect sensor 310, and the case 55 can include one or more magnets 230. In one example, the additional Hall effect sensor 310 in a headphone 30 can be configured to: a) indicate proximity to the case 55 based on a detected magnetic field from the magnet 230 on the case 55, or b) indicate proximity to the other headphone 30 in the pair based on detecting the magnetic field generated by that other headphone 30.

In some such cases, the additional Hall effect sensor 310 in a headphone 30 can be used to verify the proximity of the headphone 30 to the slot 500 in case 55, e.g., as a secondary mechanism for detecting docking in the case 55 and/or a verification mechanism for detecting docking in the case 55. In such implementations, the controllers 320 in one or both headphone(s) 30 can be configured to communicate with the controller 420 in the case 55 to verify the detected proximity/docking of the headphone 30 in case 55. In other cases, the Hall effect sensor 310 in the headphone 30 can be used independently to detect proximity between the headphone 30 and the case 55, e.g., to take a prescribed action such as initiating charging of the headphone(s) 30, entering a sleep and/or shutdown mode, pausing or stopping audio playback, etc.

In additional implementations, where the Hall effect sensor 310 in one or both headphones 30 is configured to detect the proximity to the other headphone 30 in the pair via an onboard Hall effect sensor 310, that Hall effect sensor 310 can be configured to detect the presence of a battery at the other headphone 30, the transducer 350 at the other headphone 30 and/or magnet(s) 230 at the other headphone 30. In such cases, the controller 320 at one or both headphones 30 is configured to take a prescribed action in response to detecting the proximity between headphones 30, e.g., that headphones 30 are contacting one another or within close proximity (e.g., several centimeters) of each other. In certain implementations, detecting close proximity between headphones 30 causes the controller(s) 320 to: trigger a sleep mode for the headphones 30, shutdown the headphones 30 and/or pause or stop audio playback at the headphones 30.

### Hall Effect Sensor in Both Ear Cuffs

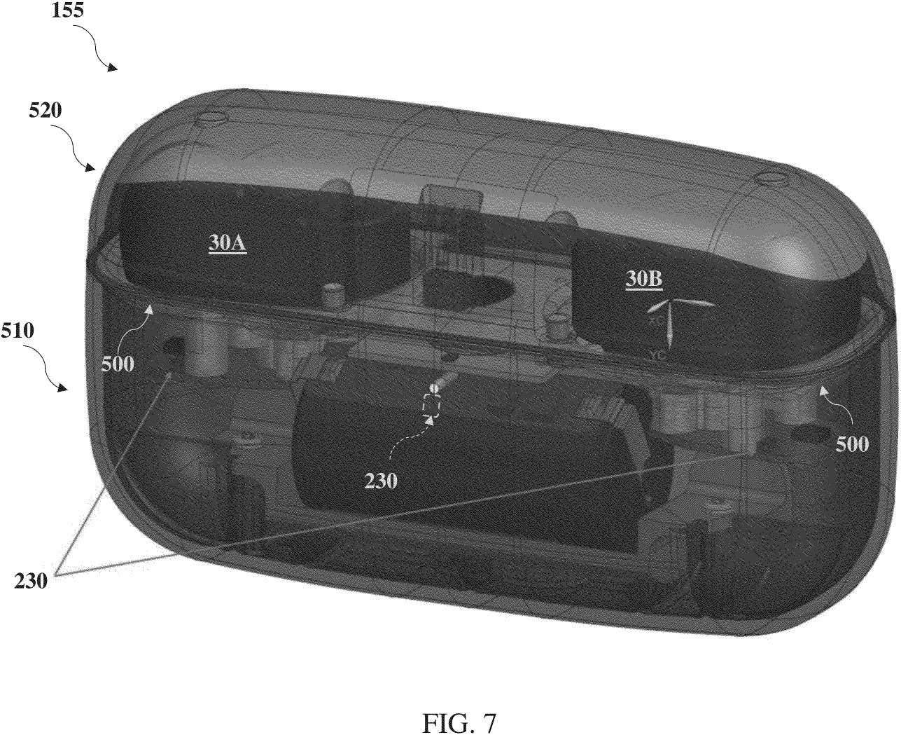

As noted herein, in certain implementations both headphones 30 in a set include a Hall effect sensor 310. Using the example depiction in FIGS. 3 and 4, each headphone 30 in a set has a Hall effect sensor 310. In such cases, the Hall effect sensor 310 in each headphone 30 can be configured to indicate proximity to a magnet 230 in the case 55 for detecting docking in the case 55, e.g., in slots 500. In such cases, the Hall effect sensor 310 in the headphones 30 detects docking (or, seating) in the slots 500, via proximity to the magnet(s) 230. Similarly to the Hall effect sensor(s) 310 depicted in FIGS. 5 and 6, FIG. 7 illustrates magnet(s) 230 in a case 155 positioned to be detectable by the Hall effect sensor(s) 310 in headphones 30 when the headphones 30 are fully seated in the case 155. In certain cases, when fully seated, the headphones 30 are interposed between two magnets 230 in the case 155. In additional, or alternative cases (as shown in phantom), a magnet 230 is positioned between the headphones 30 when docked in the slots 500 in the case 155. In some such cases, the case 155 can also include a Hall effect sensor 310 for detecting a magnetic field generated by the headphones 30, e.g., by magnets on the earbud, a transducer at the earbud, and/or a battery at the earbud. In certain of these implementations, the Hall effect sensor 310 in the case 155 is sensitive to the magnetic field generated by the transducer 350 onboard the headphones 30, to detect proximity of the headphones 30.

### Self-Coupling

In certain implementations, e.g., where earbuds each include an open-ear earpiece such as in the ear cuffs 30, each earpiece can include a coupler for coupling with a corresponding coupler on the other earpiece while not in use on a user’s ears.

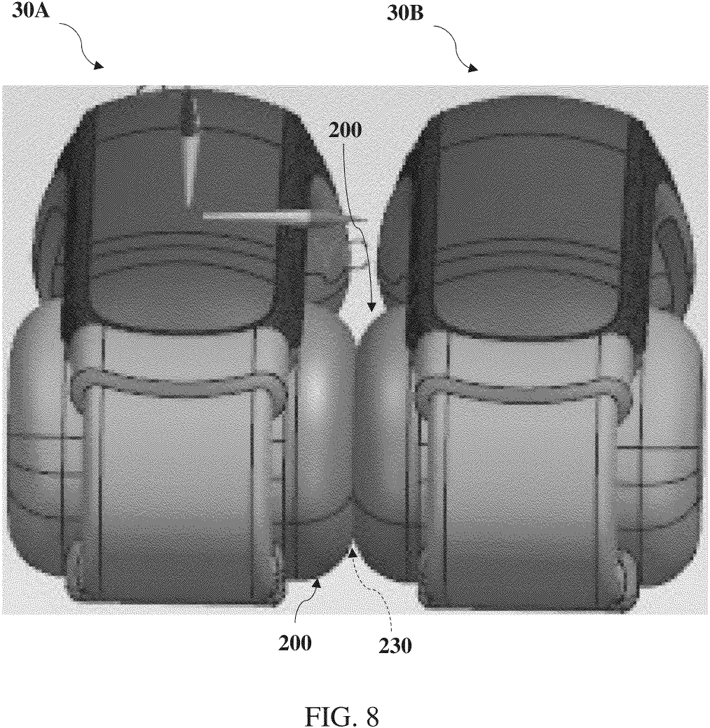

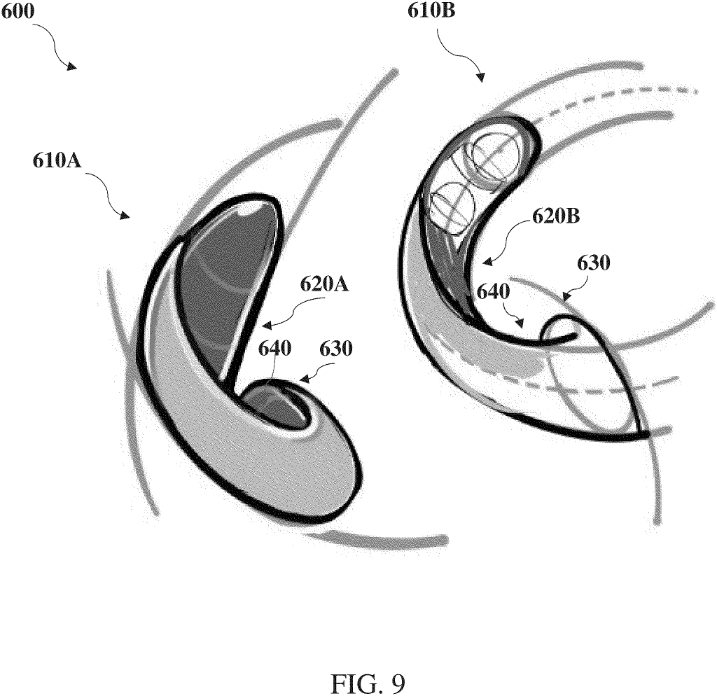

For example, as depicted in the single earpiece in FIG. 3 and in the set of earpieces in FIG. 8, a first earpiece (e.g., ear cuff) 30A includes a first coupler that includes a first magnet 230 (or set of magnets) and a second earpiece (e.g., ear cuff) 30B includes a second coupler that includes a second magnet 230 (or set of magnets, illustrated in phantom as internal to the battery barrel 200). In these implementations, the couplers (i.e., magnets) are configured to couple the first earpiece 30A and the second earpiece 30B while not in the user’s ears. In the example depiction of FIG. 9, two earpieces (e.g., ear cuff-type earbuds) 30 are depicted side-by-side. In these cases, the magnets 230 in the battery barrel 200 align the earpieces 30, e.g., in a common orientation. The magnets 230 in the battery barrel 200 of each earpiece 30 can have an opposite polarity, for example, to align sections of the earpiece 30 with the same sections of the other earbud in the pair (e.g., barrel 200 to barrel 200, acoustic module 35 to acoustic module 35). As described herein, the magnets 230 are detectable by a Hall effect sensor (e.g., Hall effect sensor 410) in a case 55 for the earpieces 30, e.g., to take a prescribed action in response to detecting docking of the earpieces 30 in the case 55.

FIG. 9 illustrates an additional implementation of an audio device 600 in which a pair of earpieces 610A and 610B include corresponding couplers 620A, 620B for coupling the earpieces 610A, 610B when not in use in the user’s ear. For example, the couplers 620A, 620B can include complementary connectors (e.g., contours) 630 for interlocking the two earpieces 610 when not in the user’s ears. In certain cases, each complementary connector 630 at least partially surrounds a space 640 that receives a portion of the complementary connector 630 in the other earpiece 610. In addition to connector 630, each earpiece 610A can include a magnet for coupling with the other earpiece 610B, and in some cases, enabling detection by a Hall effect sensor in a case for the earpieces. In some examples, the earpieces 610A, 610B are untethered such that the first coupler 620A and the second coupler 620B provide approximately all of the retaining force in coupling the earpieces 610A, 610B.

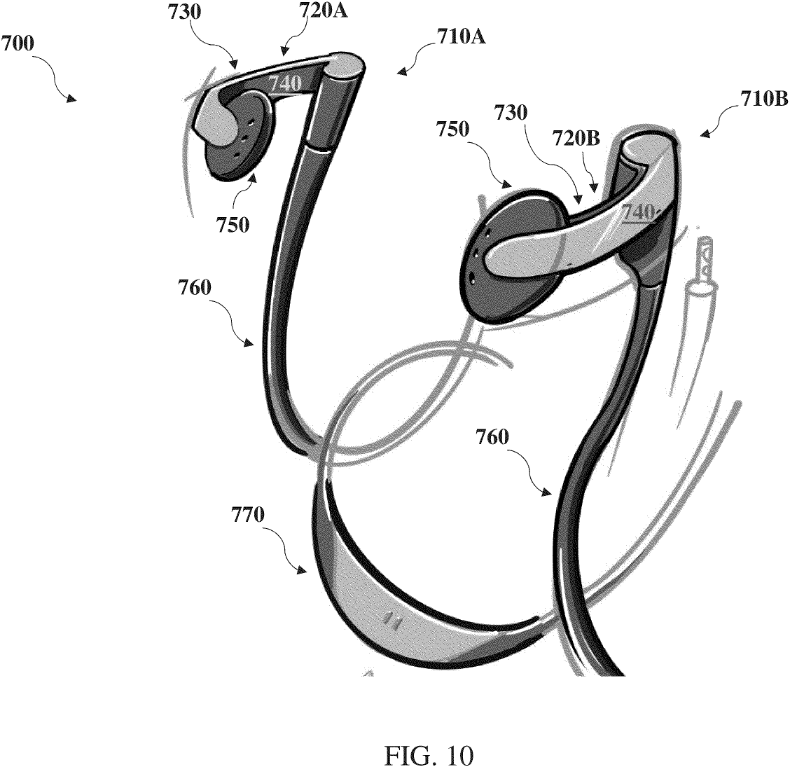

FIG. 10 shows an additional implementation of an audio device 700 in which a pair of earpieces 710A and 710B include corresponding couplers 720A, 720B for coupling the earpieces 710A, 710B when not in use in the user’s ear. For example, the couplers 720A, 720B can include complementary connectors (e.g., contours) 730 for interlocking the two earpieces 710 when not in the user’s ears. In certain cases, each complementary connector 730 is defined by an arm 740 and acoustic module 750 coupled with the arm 740, e.g., where the acoustic module 750 is angled relative to the arm 740. In particular implementations, the earpieces 710 are selectively couplable to one or more removable tether(s) 760, which can be connected to one another via a common connector 770 (e.g., including a battery and/or communication module). In any case, the couplers 720 allow the earpieces 710 to be coupled while not in use, either with or without the common connector 770.

In certain cases, the complementary connector(s) (e.g., complementary connectors 630, 730) include a snap-fit connector, an interlocking connector, a force-fit connector, or one or more magnets. In certain cases, a magnet is located on one or both earpieces 610, 710, and is configured to connect the earpieces when brought within close proximity of one another. In other cases, a snap-fit, interlocking or force-fit (e.g., pressure fit) connector can be used to press and connect earpieces 610, 710. Connectors can retain the earpieces as a coupled set until sufficient force is applied to separate the earpieces.

As described with respect to FIG. 8, couplers (e.g., magnets 230) can retain the corresponding earpieces 30 together independently of a charging case or a storage case. Similarly, as shown in FIGS. 9 and 10, the couplers 620, 720 retain the corresponding earpieces 610, 710 together independently of a charging case or a storage case. That is, magnets 230 and/or couplers 620, 720 can enable the earpieces 30, 610, and 710 to remain coupled together without the need for a charging and/or storage case. In carious implementations, the couplers (e.g., magnets 230, couplers 620, 720) are integral with the earpieces. In these cases, the earpieces can couple with one another, making it easier to store and/or transport the earpieces without loss or misplacement.

In certain cases, one or more earpieces is configured to connect with a removable tether, such as tether 760 in FIG. 10. In some cases, the tether 760 includes a connector for connecting to an external power source and/or an external data source. For example, a connector can include a power connector and/or a USB connector. In various implementations, the power connector enables charging of the earpieces 710 independently of a charging case. That is, the earpieces 710 can be charged via the power connector in the tether 760 without requiring docking in a case such as case 55 (FIGS. 5-7). In certain implementations, the tether 760 connects to both earpieces 710. In other implementations, the tether 760 connects to one of the earpieces 710, which can in turn be connected to the other earpiece 710 by a separate connector. In the depiction in FIG. 10, when the removable tether 760 is connected to each of the earpieces 710 and the couplers 720 are connected, the audio device 700 forms an annular, wearable device such as an annular piece of jewelry or a keychain. In some cases, the removable tether 760 includes a backup batter and a connector for charging the onboard battery at the earpieces 710 and/or directly powering the earpieces 710.

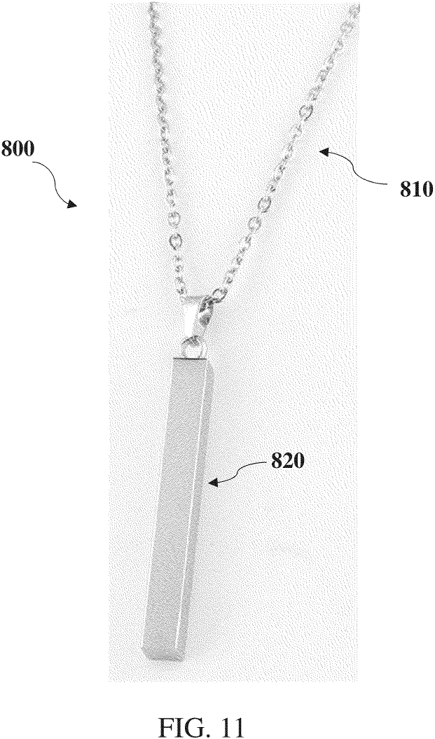

FIG. 11 shows an implementation of a removable tether 800 that includes a wearable connector (e.g., bracelet and/or necklace) 810 and a coupler 820 for connecting with earpieces. In some cases, the coupler 820 includes a metal configured to attract a magnet, such as the magnet(s) 230 in earpieces 30 and/or other earpieces described herein. In certain cases, the tether 800 can include a connector (e.g., cable) for connecting to an external power source (e.g., for charging) and/or an external data source (e.g., for software updating, data transmission, etc.).

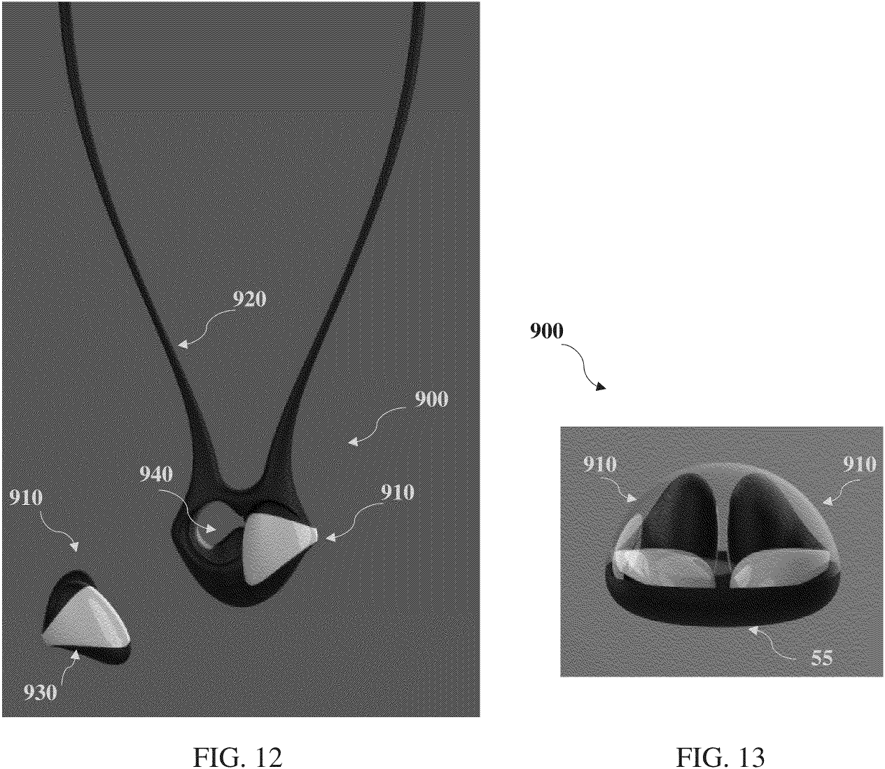

FIGS. 12 and 13 illustrate another implementation of an audio device 900 that includes earpieces 910 that are removable from a common carrier 920 (FIG. 12) and can be stored and/or charged in a case 55 (FIG. 13). In certain of these cases, the earpieces 910 include corresponding couplers 930 for connecting with couplers 940 on the common carrier 920. In certain cases, the couplers 930 on the earpieces 910 are also complementary to enable the earpieces 910 to be coupled to one another. In particular examples, the common carrier 920 can form an annular, wearable device such as a piece of jewelry or a keychain for being carried by a user. The common carrier 920 can also include a battery and/or connector to an external power and/or data source, e.g., a USB connector.

In certain additional cases, a charging dish is provided for charging an onboard battery in one of the open-ear earpieces (e.g., 30) when connected. That is, when the open-ear earpieces are connected with one another, the batteries in those earpieces can be charged wirelessly on a charging dish, e.g., via inductive charging.

In some implementations, a method of detecting docking in and/or removal of earbuds from an earbud case is based on a signal received from a Hall effect sensor in the case or in the earbuds. In certain cases, the method includes detecting the docking and/or removal of the earbuds based on a signal from a Hall effect sensor in the case, or based on a signal from a Hall effect sensor in the earbud(s). In particular implementations, the method also includes initiating charging of the set of earbuds in response to detecting docking of the set of earbuds in the earbud case.

Additional, or alternative, approaches for detecting presence of earbuds or ear cuffs in a case are described in U.S. Pat. Application No. 16/905,666 (filed on Jun. 18, 2020), which is incorporated by reference in its entirety.

In any case, the earbuds and cases shown and described according to various implementations can enable effective detection of docking events, e.g., to facilitate charging and/or power-saving actions. Further, the earbuds shown and described herein can enable for direct coupling that mitigates loss and/or misplacement. Even further, the carriers and tethers shown and described according to various implementations enable users to store and/or charge earbuds efficiently and mitigate loss and/or misplacement. Additional aspects of the earbuds, carriers and tethers function as a stylish mechanism to carry audio devices.

In various implementations, components described as being “coupled” to one another can be joined along one or more interfaces. In some implementations, these interfaces can include junctions between distinct components, and in other cases, these interfaces can include a solidly and/or integrally formed interconnection. That is, in some cases, components that are “coupled” to one another can be simultaneously formed to define a single continuous member. However, in other implementations, these coupled components can be formed as separate members and be subsequently joined through known processes (e.g., soldering, fastening, ultrasonic welding, bonding). In various implementations, electronic components described as being “coupled” can be linked via conventional hard-wired and/or wireless means such that these electronic components can communicate data with one another. Additionally, sub-components within a given component can be considered to be linked via conventional pathways, which may not necessarily be illustrated.

Other embodiments not specifically described herein are also within the scope of the following claims. Elements of different implementations described herein may be combined to form other embodiments not specifically set forth above. Elements may be left out of the structures described herein without adversely affecting their operation. Furthermore, various separate elements may be combined into one or more individual elements to perform the functions described herein.

We claim:

1. An audio device comprising:
a set of earbuds each configured to generate a magnetic field; and
a case for docking the set of earbuds, the case comprising:
a Hall effect sensor for detecting proximity to at least one of the earbuds based on the magnetic field; and
a power source for charging the set of earbuds while docked in the case.

2. The audio device of claim 1, wherein each earbud comprises an electro-acoustic transducer configured to generate the magnetic field, and wherein the Hall effect sensor is sensitive to the magnetic field generated by the electro-acoustic transducer to detect the proximity to one of the earbuds.

3. The audio device of claim 1, wherein each earbud comprises at least one magnet that generates the magnetic field.

4. The audio device of claim 1, wherein the set of earbuds comprise a pair of in-ear audio devices or open-ear audio devices that are untethered relative to one another.

5. The audio device of claim 4, wherein the earbuds comprise the open-ear audio devices.

6. The audio device of claim 5, wherein the open-ear audio devices comprise ear cuffs.

7. The audio device of claim 1, further comprising at least one additional Hall effect sensor for detecting proximity to an additional one of the set of earbuds or detecting an orientation of at least one of the set of earbuds.

8. The audio device of claim 1, wherein the Hall effect sensor is configured to detect the magnetic field from each earbud regardless of a power state of the earbud.

9. The audio device of claim 1, wherein each earbud further comprises an additional Hall effect sensor and wherein the case further comprises at least one magnet, wherein the additional Hall effect sensor in each earbud is configured to perform at least one of:
indicate proximity to the case based on a detected magnetic field from the at least one magnet, or
indicate proximity to the other one of the earbuds based on detecting the magnetic field generated by the corresponding earbud.

10. The audio device of claim 1, wherein the case is configured to initiate a charging protocol for charging the earbuds in response to the Hall effect sensor detecting proximity to at least one of the earbuds.

11. An audio device comprising:
a case comprising at least one magnet; and
a set of earbuds for docking in the case, wherein each earbud comprises a Hall effect sensor for indicating proximity to the at least one magnet to indicate that a corresponding earbud is docked in the case.

12. The audio device of claim 11, wherein the case further comprises:
an additional Hall effect sensor for detecting a magnetic field generated by each of the set of earbuds; and
a power source for charging the set of earbuds while docked in the case.

13. The audio device of claim 12, wherein each earbud comprises an electro-acoustic transducer configured to generate a magnetic field, and wherein the additional Hall effect sensor is sensitive to the magnetic field generated by the electro-acoustic transducer to detect the proximity to one of the earbuds.

14. The audio device of claim 11, wherein the set of earbuds comprise open ear audio devices.

15. An open-ear audio device, comprising:
a first open-ear earpiece housing an electro-acoustic transducer and including a first coupler; and
a second open-ear earpiece housing an electro-acoustic transducer and including a second coupler, wherein the first coupler and the second coupler are configured to couple the first open-ear earpiece and the second open-ear earpiece while not in use on a user’s ears.

16. The open-ear audio device 15, wherein the first open-ear earpiece and the second open-ear earpiece each comprise an ear cuff.

17. The open-ear audio device of claim 15, wherein the first coupler and the second coupler each comprise a magnet for coupling the first open-ear earpiece and the second open-ear earpiece.

18. The open-ear audio device of claim 17, wherein the magnets are detectable by a Hall effect sensor in a charging case for the first open-ear earpiece and the second open-ear earpiece.

19. The open-ear audio device of claim 15, wherein the first coupler and the second coupler comprise complementary connectors for coupling the first open-ear earpiece and the second open-ear earpiece.

20. The open-ear audio device of claim 19, wherein the complementary connectors comprise at least one of: a snap-fit connector, an interlocking connector, a force-fit connector, or at least one magnet.

21. The open-ear audio device of claim 15, wherein the first open-ear earpiece and the second open-ear earpiece are untethered such that first coupler and the second coupler provide approximately all of a retaining force in coupling the first and second earpieces.

22. The open-ear audio device of claim 21, wherein the first coupler and the second coupler retain the first and second earpieces together independently of a charging case or a storage case.

23. The open-ear audio device of claim 15, further comprising a removable tether configured to connect to at least one of the first open-ear earpiece or the second open-ear earpiece.

24. The open-ear audio device of claim 23, wherein the removable tether comprises a connector for connecting to an external power source or an external data source.

25. The open-ear audio device of claim 23, wherein when the removable tether is connected to the first open-ear earpiece and the second open-ear earpiece and the first coupler and second coupler are connected, the open-ear audio device forms an annular piece of jewelry or a keychain.

26. The open-ear audio device of claim 23, wherein the removable tether comprises a backup battery and a connector for at least one of charging an onboard battery at the open-ear earpieces or directly powering the open-ear earpieces.

27. The open-ear audio device of claim 15, further comprising a charging dish for charging an onboard battery in each of the open-ear earpieces when connected.

28. An open-ear audio device, comprising:
a first open-ear earpiece housing an electro-acoustic transducer and including a first coupler;
a second open-ear earpiece housing an electro-acoustic transducer and including a second coupler; and
a common connector for coupling with the first coupler and the second coupler while the first open-ear earpiece and the second open-ear earpiece are not in use on a user’s ears.

29. The open-ear audio device of claim 28, wherein the common connector comprises a tether.

30. The open-ear audio device of claim 28, wherein the common connector comprises a power connector for charging the first open-ear earpiece and the second open-ear earpiece independently of a charging case.

31. The open-ear audio device of claim 28, wherein the first coupler and the second coupler are complementary to permit direct coupling of the first open-ear earpiece to the second open-ear earpiece.

32. The open-ear audio device of claim 28, wherein the first coupler and the second coupler comprise magnets.
